(19) United States
(12) Patent Application Publication
(10) Pub. No.: US 2008/0310210 A1
(43) Pub. Date: Dec. 18, 2008

(54) Semiconductor memory device and method of operation

(76) Inventors: Dietmar Gogl, Essex Junction, VT (US); Ulrich Klostermann, Munich (DE)

Correspondence Address: SLATER & MATSIL, L.L.P., 17950 PRESTON ROAD, SUITE 1000, DALLAS, TX, 75252, US

(21) Appl. No.: 11/818,196

(22) Filed: Jun. 13, 2007

(51) Int. Cl. G11C 7/02

(52) U.S. Cl. 365/148; 365/158

(57) ABSTRACT

A memory cell is disclosed. The memory cell comprises a storage element including a first terminal and a second terminal, and a select transistor including a first terminal, a second terminal and a control terminal. The voltage at the control terminal of the select transistor affects a current flowing between the first terminal and the second terminal. The first terminal of the select transistor is coupled to the second terminal of the storage element. A bit line is coupled to the first terminal of the storage element, a first word line is coupled to the control terminal of the select transistor, and a second word line is coupled to the second terminal of the select transistor.

### TECHNICAL FIELD

This invention relates generally to semiconductor devices, and more particularly to a memory device and method.

### BACKGROUND

Semiconductors are used in integrated circuits for electronic applications, including radios, televisions, cell phones and personal computing devices, as examples. Types of semiconductor devices include dynamic random access memory (DRAM), static random access memory (SRAM) and flash memory which use charge to store memory, magnetic random access memory (MRAM), which uses a magnetic field to store memory, phase change random access memory (PCRAM), which uses a crystalline state to store memory, and conductive bridging random access memory (CBRAM), which uses a conducting path of silver atoms to store memory.

Newer forms of memory such as MRAM, PCRAM and CBRAM contain memory elements whose memory state is read by measuring the impedance between two terminals. One common method of incorporating these memory elements into a functional memory is by creating a two dimensional array of these memory cells and placing each memory cell in series with a switch. Each row of the array represents a word in memory and each column of the array represents an output bit. To read a word from memory, each switch in the row to be read is closed while each switch in the remaining rows is kept open. All of the memory cells in a column are connected together in a wired-OR configuration, so that, in theory, the only bit in a column that draws current is the selected bit. By setting the bit line to a known voltage and measuring the current being drawn by a bit line, the memory state of a bit in a selected word can be determined.

As electronic components are getting smaller and smaller, along with the internal structures in integrated circuits, the problem of device leakage becomes problematic. Transistor technology currently used in memory arrays suffers from the problem that a reduction in device size, while maintaining suitable on-currents, leads to increased off-currents in the device. The leakage currents of deselected devices along a bit line can reach levels high enough to disturb a read or a write operation in small geometry processes.

One possible solution to the problem of leakage currents in memory arrays is to implement new transistor devices, such as finFETs, that exhibit lower leakage currents. These new transistor structures, however, can require considerable technology effort and are often more expensive to fabricate due to extra masks and processing steps. Thus, there is a need for improved memory array architectures and methods that exhibit lower leakage currents and do not require changes and advances in device technology to achieve this goal.

### SUMMARY OF THE INVENTION

In one embodiment, a memory cell comprises a storage element including a first terminal and a second terminal, and a select transistor including a first terminal, a second terminal and a control terminal. The voltage at the control terminal of the select transistor affects a current flowing between the first terminal and the second terminal. The first terminal of the select transistor is coupled to the second terminal of the storage element. A bit line is coupled to the first terminal of the storage element, a first word line is coupled to the control terminal of the select transistor, and a second word line is coupled to the second terminal of the select transistor.

### DESCRIPTION OF THE DRAWINGS

For a more complete understanding of the present invention, and the advantages thereof, reference is now made to the following descriptions taken in conjunction with the accompanying drawings, in which:

FIG. 1 is a schematic diagram of an embodiment FET array memory; and

FIGS. 2 is a flow chart of an embodiment method.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION

The making and using of the presently preferred embodiments are discussed in detail below. It should be appreciated, however, that the invention provides many applicable inventive concepts that can be embodied in a wide variety of specific contexts. The specific embodiments discussed are merely illustrative of specific ways to make and use the invention, and do not limit the scope of the invention.

The invention will be described with respect to preferred embodiments in a specific context, namely an NMOS FET and memory element memory structure. The invention may also be applied, however, to other semiconductor structures.

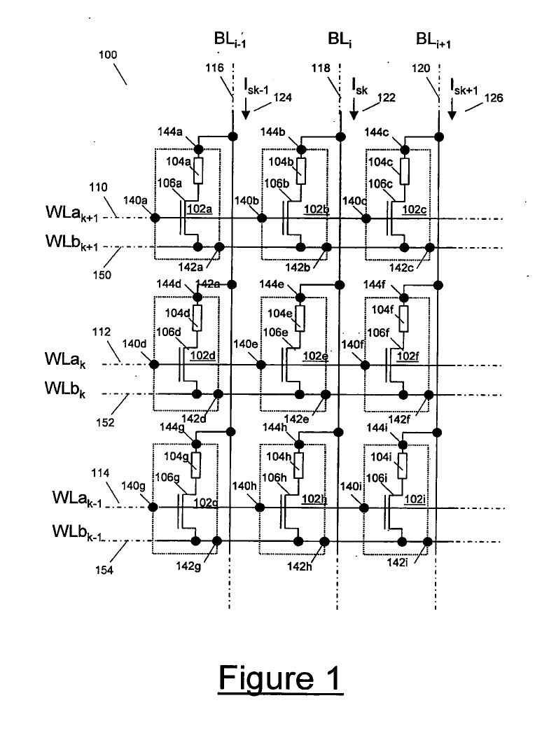

Before discussing details of preferred embodiments, it will be instructive to consider conventional memory structures. Much of the discussion with respect to FIG. 1 also applies to embodiments of the invention and, as a result, various details will not be repeated.

FIG. 1 illustrates a first embodiment FET memory structure 100. The structure is made up of memory cells 102a-102i, first word lines WLaₖ₋₁ 114, WLaₖ 112, and WLaₖ₊₁ 110, second word lines WLbₖ₋₁ 154, WLbₖ 152, and WLbₖ₊₁ 150 and bit lines BLᵢ₋₁ 116, BLᵢ 118, and BLᵢ₊₁ 120. The memory cell in FIG. 1 shows 9 representative memory cells configured in a 3×3 memory array for illustrative purposes, however, the bit lines and word lines can continue beyond the illustrated array and can support a memory array of any practical dimension.

Each memory cell 102 is made up of a switch transistor 106, typically implemented as an NFET device, and a memory element 104. Each memory cell 102 has a common terminal 142 coupled to a controlled terminal of the switch transistor 106, a control terminal 140 coupled to the control terminal of the switch transistor 106, and an output terminal 144 coupled to the output terminal of the memory cell 102. In a preferred embodiment of the present invention, switch transistor 106 is implemented as an NMOS device whereby the control terminal 140 is coupled to the gate of the NMOS device and the common terminal 142 is coupled to the source of the NMOS device.

The memory element 104 can physically be implemented in a number of ways. For example, an MRAM element, a PCRAM element, or another memory element structure could be used to physically implement the memory element. For this memory structure, however, the resistance of the memory element is dependent on the state of the memory element. In an MRAM storage cell, for example, the spin of the electrons in the cell determines the state of the memory. A bit, e.g. a “0” or “1” may be stored in the storage element by changing the orientation of magnetic fields within layers present within the storage element. Because the resistance of the element is dependent on the orientation of the magnetic field within the layers of the storage element, the state of the element can be sensed by measuring the resistance of the element. For example, a binary “1” can be defined when the cell is programmed to have a low resistance and the binary “0” can be defined when the cell has a high resistance. Alternatively, a binary “0” can be defined when the cell is programmed to have a low resistance and the binary “1” can be defined when the cell has a high resistance. To read the memory, the resistance is measured by applying a voltage across the memory element and measuring the current with a sense amplifier. Switch transistor 106 is used as a switch to either select or deselect the memory cell 102 for reading or writing.

Memory array 100 is arranged in a wired-or configuration. Each word in the array is selectable by a first word line. For example, the word made of memory cells 102d, 102e, and 102f are selected by first word line, WLaₖ 112. Each memory cell corresponding to a particular output bit is tied together on a bit line. For example, memory elements 102b, 102e and 102h are all tied to bit line, BLᵢ 118. When the word of memory corresponding to first word line WLaₖ 112 is being read, WLaₖ 112 is set to a voltage that exceeds the threshold voltage of the switch transistors 106d, 106e, and 106f. Remaining word first word lines WLaₖ₋₁ 114 and WLaₖ₊₁ 110 are set to ground so that NFET switches 104a, 104b, 104c, 104g, 104h, and 104i are turned off. Bit lines that are to be read, for example, BLᵢ₋₁ 116, BLᵢ 118, and BLᵢ₊₁ 120 are set to a read voltage.

As an example, the read method used in conventional art FET memories will be described. If this memory is configured as a conventional art FET memory, second word lines WLbₖ₋₁ 154, WLbₖ 152, and WLbₖ₊₁ 150 are all set to ground. Because the sources of memory switch transistors 106a-i are directly tied to ground, conventional art FET memories typically do not have second wordlines WLbₖ₋₁ 154, WLbₖ 152, and WLbₖ₊₁ 150 as depicted in FIG. 1.

When the read voltage is applied, a measurable current Iₛₖ 122 in bit line BLᵢ 118 will flow through memory element 104e and NFET switch 106e if memory element 104e is programmed to be in a low resistance state. For example, a binary “1” could be read if a binary “1” is defined to be represented by a low resistance state. A sense amplifier (not shown) can be used to detect the presence of Iₛₖ 122 so that the state of the memory element 102e can be determined. In binary memories, the sense amplifier typically compares the bit line current to a threshold. If the memory element 104e is programmed to be in a high resistance state, however, Iₛₖ 122 will be small and a binary “0” may be read from memory. Alternatively, in other embodiments of the present invention, a binary “1” could be defined to if the memory element is in a high resistance state and a binary “0” could be defined if the memory element is in a low resistance state.

In modern, small geometry silicon process, where gate lengths are less than 100 nm, however, the FET switches may exhibit leakage current when the gate to source voltage is less than the threshold. This leakage may be, for example, the result of sub-threshold conduction. In large memory arrays with many word lines this leakage becomes problematic. If devices in the row connected to BLᵢ (i.e. 106b and 106h) each have a leakage current of 100 nA, then the read line will conduct 200 nA even when the memory is programmed to be in a high resistance state. If the bit line is connected to a significant number of memory devices, then the leakage current could become on the order of a programmed bit, thus either making the memory unreadable, or reducing the reliability and noise tolerance of the memory.

In the preferred embodiment of the present invention, errors caused by leakage current of the switch transistors 106a-i are minimized by a method of reading the memory. When a memory cell is read, the source of the switch transistor 106 in the memory cell to be read is kept at ground, the gate of the switch transistor is set to a voltage exceeding the switch transistor's 106 threshold, and the bit line to be read is set to a read voltage so that a voltage is developed across the memory element resistance 104. For example, if memory cell 102e is to be read, word line WLaₖ 112 is set to a voltage exceeding a read threshold, typically 400-500 mV in a 70 nm process technology, word line WLbₖ 152 is set to ground, and bit line BLᵢ 118 is set to a read voltage, typically between about 0.1V and 1 V.

In the preferred embodiment of the present invention, a memory cell is deselected by applying a voltage at the source terminal of the switch transistor 106 that approximates the read voltage applied at the bit line, and applying a voltage at the gate of the switch transistor 106 that turns off the switch. In preferred embodiments of the present invention, this gate voltage is ground voltage, but in other embodiments it could be voltages other than ground. By applying a voltage at the source of the switch transistor 106 close to the voltage applied at the bit line connected to the memory cell, the source-drain voltage of the switch transistor 106 is very small, which minimizes any leakage current developed as a result of a potential difference across the source and drain of the switch transistor 106. In a preferred embodiment of the present invention, the source-drain voltage of a deselected switch transistor is kept at under 10 mV to 20 mV. Such a small source-drain voltage can keep the leakage current of switch transistor 106 to a factor of 10 to 50 less than the leakage current seen in the conventional embodiment described herein above, where the source-drain voltage of a deselected switch transistor is typically between 100 mV to 1V.

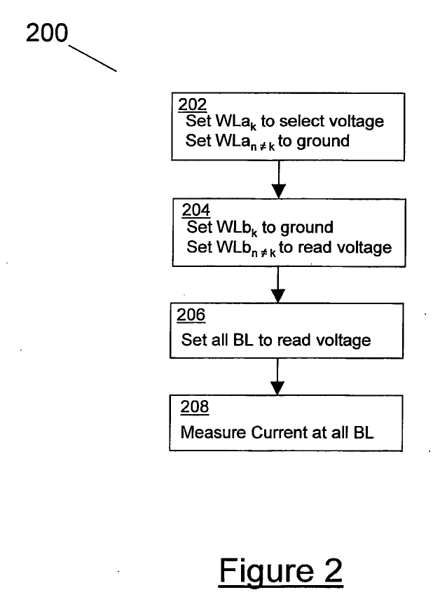

For example, if the word consisting of memory cells coupled to word lines WLaₖ 112 and WLbₖ 152 is being read, bit lines BLᵢ₋₁ 116, BLᵢ 118, and BLᵢ₊₁ 120 are set to a read voltage, word lines WLbₖ₋₁ 154 and WLbₖ₊₁ 150 are set to a voltage preferably within 10 mV to 20 mV of the read voltage, and word lines WLaₖ₋₁ 114 and WLaₖ₊₁ 110 are set to a voltage, preferably ground, that shuts off the switch transistor 106 in the deselected memory cells. In the illustration in FIG. 2, the source voltage of deselected switch transistors 106a-c, and 106g-i are kept within 10 mV to 20 mV of the drain voltage, so that leakage current through the deselected transistors are minimized. Bit line current flow Iₛₖ 122, for example, will then be primarily dependent on the programmed resistance of memory element 104e, current flow Iₛₖ₋₁ 124 will be primarily dependent on the programmed resistance of memory element 104d, and current flow Iₛₖ₊₁ 126 will be primarily dependent on the programmed resistance of memory element 104f.

Turning to FIG. 2, a flowchart 200 describing a preferred embodiment method of reading a FET memory is shown. In the first step 202, the first word line WLaₖ on the k^{th} row, the row to be read, is set to select voltage. The first word lines WLa_{n≠k} on the remaining rows n≠k is set to ground. In step 204, the second word line on the k^{th} row, the row to be read, WLbₖ is set to ground. The second word lines WLb_{n≠k} on the remaining rows n≠k is set to a read voltage, typically between about 0.1V and 1 V. In step 206 all bit lines BL are set to a read voltage. Alternatively, only a subset of the bit lines may be set to a read voltage if not all of the bit lines need to be read for a particular application. In step 208, the bit line currents are read to determine the state of the memory.

The implementation of the control method described in FIG. 2 is typically implemented by a memory controller and/or other circuitry known in the art. The specific implementation and timing details, however, are application, process and memory type specific.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A memory cell comprising:
a storage element including a first terminal and a second terminal;
a select transistor including a first terminal, a second terminal and a control terminal, wherein a voltage at the control terminal affects a current flowing between the first terminal and the second terminal, the first terminal of the select transistor being coupled to the second terminal of the storage element;
a bit line coupled to the first terminal of the storage element;
a first word line coupled to the control terminal of the select transistor; and
a second word line coupled to the second terminal of the select transistor.

2. The memory cell of claim 1, wherein the memory cell is one memory cell in an array of memory cells, the memory cell being part of a row and column of the array, wherein the bit line is coupled to the first terminal of each memory cell in the column, the first word line is coupled to the control terminal of each memory cell in the row, and the second word line is coupled to the second terminal of each memory cell in the row.

3. A method of operating a memory cell, the method comprising:
enabling the memory cell, wherein the enabling comprises,
switching a first word line to a first voltage, the first word line coupled to a control terminal of the memory cell,
switching a second word line to a second voltage, the second word line coupled to a common terminal of the memory cell, and
applying a third voltage to a bit line, the bit line coupled to an output terminal of the memory cell, wherein the potential difference between the control terminal and common terminal is within a range of voltages that causes the output terminal to conduct a current which depends on an internal state of the memory cell; and
disabling the memory cell, wherein the disabling comprises,
switching the first word line to a fourth voltage,
switching the second word line to a fifth voltage, and
applying the third voltage to the bit line, wherein the potential difference between the control terminal and common terminal is within a range of voltages that substantially prevents the output terminal from conducting a current.

4. The method of claim 3, wherein the fourth voltage is substantially equal to the second voltage and wherein the fifth voltage is substantially equal to the third voltage.

5. The method of claim 3,
wherein the memory cell is disposed within a two dimensional array of memory cells comprising a plurality of rows and plurality of columns,
wherein each row comprises a separate first word line coupled to the control terminals of the memory elements in the row, and a separate second word line coupled to the common terminals of the memory elements in the row, and
wherein each column comprises a separate bit line coupled to the output terminals of the memory elements in the column.

6. The method of claim 3, wherein the memory cell comprises:
a memory element comprising a first terminal and a second terminal, the second terminal being coupled to the output terminal of the memory cell.;
a switch element comprising a control terminal, a common terminal, and an output terminal, wherein the control terminal is coupled to the control terminal of the memory cell, the common terminal is coupled to the common terminal of the memory cell, and the output terminal is coupled to the first terminal of the memory element

7. The method of claim 6, wherein the switch element comprises an MOS device.

8. The method of claim 6, wherein the resistance between the first terminal and second terminal of the memory element is programmable.

9. The method of claim 8, wherein the memory element comprises an MRAM memory element.

10. The method of claim 8, wherein the memory element comprises a CBRAM memory element.

11. The method of claim 8, wherein the memory element comprises a PCRAM memory element.

12. The method of claim 7, wherein the MOS device comprises an NMOS device and wherein the second and fourth voltages are ground, and the first voltage exceeds a threshold of the NMOS device.

13. The method of claim 5, wherein the enabling further comprises enabling a plurality of memory elements in one row of elements, and wherein the disabling further comprises disabling a plurality of memory elements in the rows of elements that have not been enabled.

14. The method of claim 3, the method further comprising writing information into the memory cell.

15. A semiconductor memory comprising:
an array of memory cells, the array comprising a first number of rows and a second number of columns, wherein each memory cell comprises a common node, a control node, and an output node;
a first number of first word lines, wherein each first word line is coupled to the control node of each memory cell in a particular row; and
a first number of second word lines, wherein each second word line is coupled to the common node of each memory cell in a particular row;
a second number of bit lines, wherein each bit line is coupled to the output node of each memory cell in a particular column, wherein a row of memory is read by applying a ground voltage on the second word line corresponding to the row to be read, applying a voltage which exceeds a read threshold on the first word line corresponding to the row to be read, applying a read voltage to each bit line, applying a voltage that does not exceed a read threshold on the first word lines that do not correspond to the rows to be read, and applying a voltage substantially equal to the voltage on the second word lines that do not correspond to the row to be read whereby a leakage current on the memory cells not being read is minimized.

16. The semiconductor memory of claim 15, wherein each memory cell comprises:
a switch device comprising a first terminal, and second terminal and a third terminal, wherein the resistance between the second terminal and the third terminal becomes lower when the voltage between the first terminal and the third terminal exceeds the read threshold, and wherein the first terminal is coupled to the control input of the memory cell, and the third terminal is coupled to the common node of the memory cell; and
a memory element comprising a first terminal and a second terminal, the first terminal coupled to the second terminal of the switch device and the second terminal coupled to the output of the memory cell, the memory cell having a resistance that depends on a programmed state.

17. The semiconductor memory of claim 16, wherein the switch device comprises a transistor.

18. The semiconductor memory of claim 17, wherein the transistor comprises an NMOS device.

19. The semiconductor memory of claim 16, wherein the memory element comprises an MRAM.

20. The semiconductor memory of claim 16, further comprising a second number of sense amplifiers, each sense amplifier coupled to one bit line, wherein the sense amplifier senses the current at the outputs of the memory cells coupled to a bit line.

21. A semiconductor device comprising,
a semiconductor body;
an array of memory cells disposed on the semiconductor body, the array comprising rows and columns;
a plurality of first word lines, each word line coupled to the memory cells along a row of the array of memory cells;
a plurality of second word lines, each word line coupled to the memory cells along a row of the array of memory cells;
a plurality of bit lines, each word line coupled to the memory cells along a column of the array of memory cells; and
a memory controller, wherein, when reading a row, the memory controller sets the second word line of the row to be read to ground and the first word line of the row to be read to a voltage exceeding a read threshold, and sets the second word lines of the rows not to be read to a first read voltage and the first word line of the row not to be read to a voltage not exceeding a read threshold, and the bit lines on the columns to be read to a second read voltage.

22. The semiconductor device of claim 21, further comprising a plurality of sense amplifiers, each sense amplifier coupled to a bit line, wherein the sense amplifier senses current drawn from each bit line.

23. The semiconductor device of claim 21, wherein each memory cell comprises a switch and a memory element, the switch and the memory element coupled in series, wherein the state of the element is represented by the impedance of the memory element.

24. The semiconductor device of claim 23, wherein the switch comprises a transistor.

25. The semiconductor device of claim 24, wherein the transistor comprises an NMOS device.

26. The semiconductor device of claim 23, wherein the memory element is an MRAM element.

27. The semiconductor device of claim 23, wherein the memory element is a PCRAM device.

28. The semiconductor device of claim 23, wherein the memory element is a CBRAM device.

29. The semiconductor device of claim 21, wherein the first and second read voltages are selected to minimize leakage current.
